(19) United States
(12) Patent Application Publication
(10) Pub. No.: US 2010/0033354 A1
(43) Pub. Date: Feb. 11, 2010

(54) TOUCH SENSITIVE DEVICE

(75) Inventor: Finn Ejlersen, Holstebro (DK)

Correspondence Address: JAMES C. WRAY, 1493 CHAIN BRIDGE ROAD, SUITE 300, MCLEAN, VA, 22101, US

(73) Assignee: BANG & OLUFSEN A/S, STRUER DENMARK (DK)

(21) Appl. No.: 12/448,265

(22) PCT Filed: Dec. 17, 2007
(86) PCT No.: PCT/DK2007/000548

§ 371 Date: Jul. 13, 2009

(51) Int. Cl. H03K 17/94

(52) U.S. Cl. 341/33

(57) ABSTRACT

A sensitive precision detector to sense user given control input in terms of activation on a cover plate by moving the finger with an easy touch, or with a force vertically or with a force in circular or elliptical movements on the surface of the cover plate. The precision detector is configured as a structure having the cover plate made in a conducting material. A first member constitutes the cover plate which is pre-processed to have a certain ability to be depressed along the Z-axis upon activation from a finger touch. The first member constitutes the one electrode of a capacitor and having the second member as the other electrode of the capacitor. Change in the capacitance is detected upon activation with a force provided on the cover plate.

### FIELD OF THE INVENTION

The present invention relates to an improvement in an apparatus comprising touch sensitive input detection means, in particular an apparatus having metal surfaces.

In the prior art many different solutions support touch sensitive man-machine-operation in the control of the equipment, with the operational means implemented as touch pads. Depending on which material constitutes the surface of the equipment, different technologies are applied. Surfaces may be of glass, plastics and metal and different means and technologies are applied accordingly. Capacitive detection, strain gauge- and piezo-electric principles are known technologies.

From US 2003/0028 346 a device is known which is able to detect the position of a finger in relation to a touch sensitive scrolling pad. The touch sensitive characteristics are constructed by superposing two oppositely arranged wedge shaped conductors which together form a capacitor. As a finger slides along one wedge shaped conductor the capacitance will change due to the relative change in conductivity between the finger and the conductors. This change occurs due to the wedge shape of the conductors such that although the distance between the conductors is constant, the conductors' characteristics change due to the change in thickness. This system, however, re-quires that the finger or implement scrolling on the conductor arranged for this purpose is conductive in order to change the capacitance.

An further example is described in WO-A-2004/104537 wherein a capacitor system, comprising a number of capacitor units are arranged in a grid, and correlated by a controlling unit. Each capacitor comprises two spaced capacitor plates, where the distance is accurately determined. The grid of capacitor units are then covered by an input plate. When a user touches the input plate, each capacitor will change capacitance due to the change in distance between capacitor plates in each of the units. The input from all the units in the grid is used in order to determine the location of the finger. The units will be depressed differently, depending on their distance to where the finger touches the plate. In a simple embodiment four units are used, where the units are arranged on orthogonal axis. The depression will then generate capacitance differences in the four units, and due to the physical arrangement the position between the different units will localise the finger.

With the present invention a variant of the capacitive detection is disclosed.

The proposed principle makes it possible to implement the controls as part of the metal front panel without any seams, openings or disruptions in the surface of the front panel and thus on the surface of the apparatus.

This is a addressed with an apparatus according to the present invention including a front panel, where input to the apparatus is performed via the front panel, where at least the side of the front panel opposite to the apparatus front side is provided with an electrically conductive material or the front panel itself is made from a conductive material and where a detection device for sensing user given control commands in terms of activation on said front panel, where said front panel has an extent in a first plane defined by an X and Y axis, with the finger by a force along a Z-axis substantially perpendicular to the X-Y plane of said front panel said device comprising:
a first member being the front panel which is pre-processed to have a certain ability to be depressed along the Z-axis upon activation from a finger; and;
said first member being configured to act as one electrode of a capacitor; and;
a second member being made from a conductive material and configured to act as the other electrode of a capacitor;
where the first member electrode being electrical isolated from the second member electrode; and
where the pre-processing of the first member is superposed the second member, and
the first member and the second member are assembled such that the assembly constitutes an electrical capacitor having as electrodes, the electrodes of the first and the second members.

As opposed to the existing piezo-electric technology, the proposed principle enables long time key force detection which is very useful e.g. for scrolling. With piezo-electric technology the element is only able to detect changes, i.e. that a depression occurs. The time which the element is depressed is not registered. The present invention on the other hand combines the physical touch characteristics of the piezo-electric element with the electric characteristics of the conductor device.

As the front panel of the apparatus constitutes one of the elements in the conductor element, a touch on the front panel will change the distance between the two conductors and thereby the conductance which the CDC and the algorithm will be able to detect as an input. The period which the distance is or remains changed from the initial distance indicates the period of time and as such the length of the touch is also registered. A further characteristic which may be determined is the distance change between the two conductor plates being a direct function of the force used to depress the front panel.

These three different characteristics may cooperate in order to provide various input such that for example a light quick touch may turn on a device, a prolonged touch may scroll through menus or listings and the pressure applied to the conductor plates and thereby the distance change between the two conductor plates may indicate the desired scrolling speed.

By furthermore pre-processing the front panel in areas superposing the second member electrode the material thickness may be such that only very slight touches create the desired input. In some applications used for testing the present invention, the front element being the first member was an aluminium plate approximately 0.6 mm thick. It is very desirable to be able to design different types of electronic apparatuses having real metal surfaces or at least homogenous surfaces. In the typical test samples the pre-processed areas superposing the second member being the second part of the conductor were machined down to approximately one tenth of a millimetre such that only slight touches were necessary in order to depress the zones superposed the second members. These zones may be marked on the front side of the panel or in other manners be indicated.

In practice the construction comprised a PCB carrying the second conductor. The pre-processed section of the apparatus' front panel was superposed the second conductor. The difference in material thickness, i.e. between the original material thickness and the pre-processed material thickness, determined the distance between the conductor plates. In this manner a very slim device was created and at the same time the advantages of the present invention were utilised.

The front plate may also be made from plastics, glass or other non-conductive material in which case a conductive layer was arranged on the rear side of the front panel in order to constitute the first member of the conductor. The conductive layers only had to be applied in the zone superposing the second member, and in practice only the pre-processed sections were provided with a conductive layer which layer was in electrical connection with a CDC (Capacity to Digital Converter). A preferred CDC is for example of the type Analog Devices AD7142 or similar. As the magnitude of the force can be detected the scrolling speed can be proportional to the key force.

In addition the touch sensitive device as disclosed in the invention is very sensitive in detecting the touch from the finger of the user, without being noise sensitive.

In summary the characteristics of the device having plurality of advantages are:
Simple construction.
Long time key force can be detected.
Magnitude of force can be detected, thus e.g. scroll speed in an application can be dependent on the force applied.
Can be extremely sensitive, thus applied force <0.25 N can be detected.
Reliable: no ‘moving’ parts.
Long lifetime: no wear and tear.
Very high noise immunity; can be completely shielded against electrical noise, (covered by a metal plate).
Can be completely sealed against dirt and water, can work under water.
Since it is the deformation of the metal plate that is detected the key can be activated with gloves or pen/stick, conductive or nonconductive materials.
Flexible design, as the metal plate could be replaced by any other conductive material, e.g. carbon coated plastics, film printed with conductive ink like carbon or silver, etc.

The touch sensitive principle may be applied in any type of equipment like consumer electronics, cell phones, cars, instrumentation, media player, PC's etc.

In a second preferred embodiment of the invention a plurality of pre-processed sections are arranged in an array or circular configuration, superposed a corresponding array or circular configuration of second members, whereby a force along the horizontal plane of the front panel will generate a dynamic input, such that the relative movement of the force along the array or circle generates the input.

With this configuration the apparatus in addition to the functionalities already mentioned above, furthermore makes it possible to register input from a horizontal movement of a touch on the front panel of the apparatus. Thus scrolling, not only by depressing more or less in the Z-direction is possible, but also scrolling or selecting by horizontal movement is possible.

Further advantageous embodiments are recited in the further dependent claims.

For example in a third aspect of the invention an electrical circuit that detects the depressing magnitude of the user given force on the surface of the apparatus is provided.

The construction in a further embodiment may be constructed such that the physical distance between the first and the second member is obtained fully or partly as part of the support material of the assembly. The support material, is in this connection either part of the front panel, or non-conductive material pieces, arranged between the front plate and the substrate on which the second member is mounted, typically a PCB.

A detection device, where the force of the finger activated in the Z-axis direction is detected as a magnitude of force with proportional changes in the capacity of the capacitor that is constituted by the first member electrode and the second member electrode.

The calculated change in capacity is based on the formula:

The capacity C between the metal plate and the conductive pad is:

$$C = {ɛ}_{o} \times {ɛ}_{r} \times \frac{A}{d}$$

### Where

A is the area of the conductive pad, and
d is the distance (air gap) between the metal plate and the conductive pad.
∈ₒ is the dielectric constant in vacuum.
∈ᵣ is the dielectric constant of the material in between the two electrodes of the capacitor.

If a force is applied to the metal plate the plate is deformed (bent downwards) causing the distance d to become smaller. Thus the capacity C becomes larger.

The capacity is measured with a high resolution capacity-to-digital converter (CDC) and fed into a microprocessor for further signal processing. A standard CDC with 16 bits of resolution is sufficient.

The CDC may be configured in a grounded mode of operation. The first member cover plate is connected to ground. The second member pad is connected to the input of the CDC.

When a button is pressed, the capacitance that is measured by the CDC, changes. When the capacitance changes to such an extent that a preset threshold is exceeded, the CDC registers this as a button touch/activation.

Preprogrammed threshold levels are used to determine if a change in capacitance is due to a button being activated.

The sensitivity is dependent on the thickness and stiffness of the metal, the nominal distance between the electrodes of the capacitor, the diameter of the detector cell and signal to noise of the CDC.

In a preferred embodiment with a surface plate with a thickness of 0.5 mm aluminum, and 0.1 mm gaps between the electrodes and the cell with a 17 mm diameter it is possible to detect <25N with the CDC. Thus, a light touch is enough to activate this button.

In a preferred embodiment a control function having variable speed may be provided. The proportional changes detected according to the force may be used to provide a control function that acts with a speed according to the applied force. The higher force the higher speed and the lower force the lover speed.

In the following a preferred embodiment of the invention will be described with reference to the drawings:

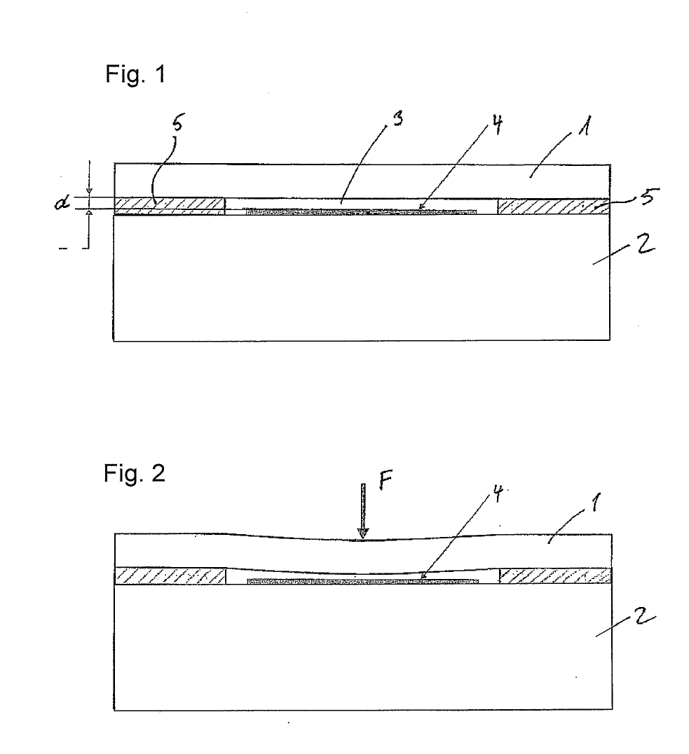

FIG. 1: This illustrates a side view of one embodiment of the invention.

FIG. 2: This illustrates a side view of one embodiment of the invention when the user has activated a force on the first member surface.

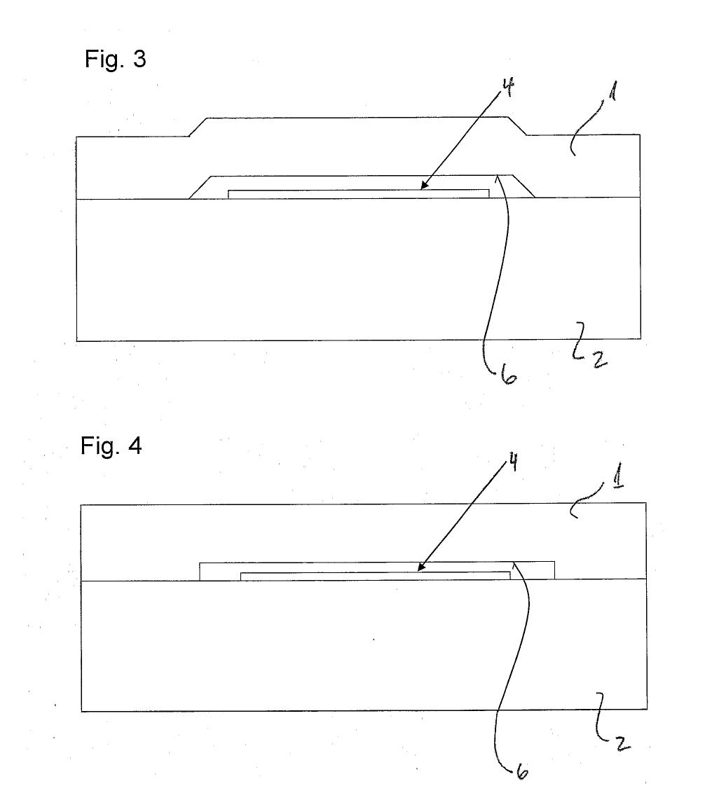

FIG. 3: This illustrates a side view of another embodiment of the invention.

FIG. 4: This illustrates a side view of yet another embodiment of the invention.

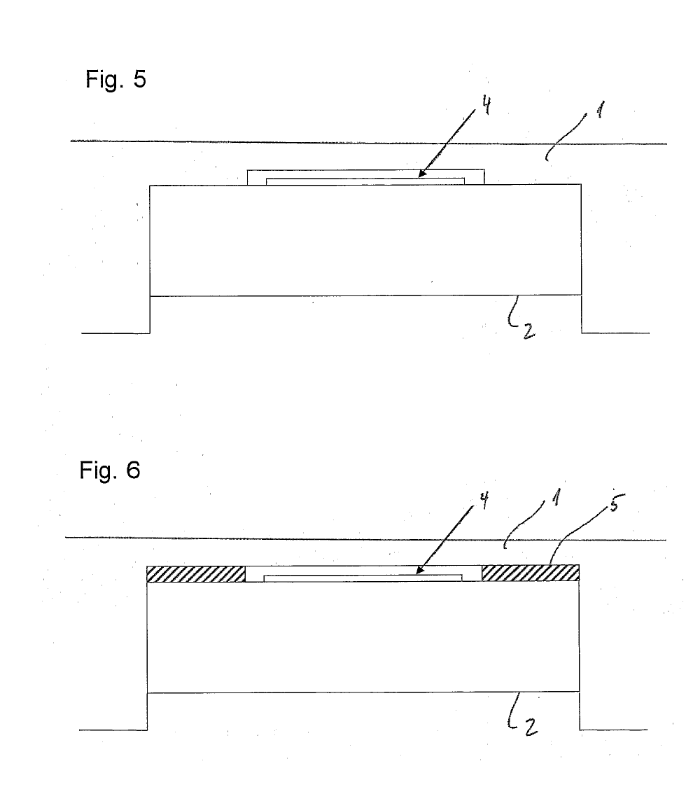

FIG. 5: This illustrates a side view of yet another embodiment of the invention.

FIG. 6: This illustrates a side view of yet another embodiment of the invention.

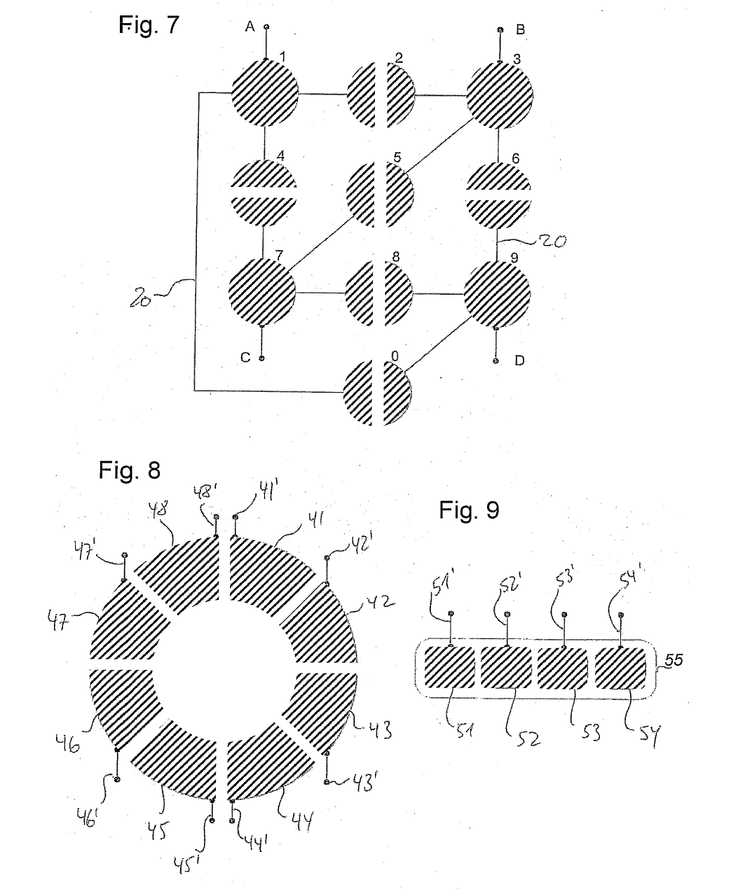

FIG. 7: This illustrates the outline of a key matrix for a preferred embodiment of the invention.

FIG. 8: This illustrates the outline of a circular touch pad for a preferred embodiment of the invention.

FIG. 9: This illustrates the outline of a scroll bar touch pad for a preferred embodiment of the invention.

### DETAILED DESCRIPTION

In FIG. 1 a preferred embodiment is illustrated, where the first member cover plate (1) is a metal plate in aluminium or stainless steel. It's pre-processed to have a very thin thickness (d) where the plate is flexible and has the ability to bend in response to the touch performed by the finger of the user.

The cover plate (1) is electrically isolated from the second member (4), which is a conductive pad. The insulation (3) between the first and the second member (1,4) may be simple air, or some kind of nonconductive flexible filler material.

The first member (1) must have the necessary room to bend into (thickness d), to obtain the necessary change in capacity of the capacitor that is constituted by the first and the second member.

The second member may be mounted on a PCB (2), having the electrical connection established at the same time (not illustrated). A nonconductive spacer material (5) supports the first member (1) in a proper position in relation to the second member (4). Electrical connection to the first member may be established through the spacer onto the PCB (2).

Alternative to the PCB (2) some kind of nonconductive material may be used as carrier of the second member conductive pad (4) and carrier of the first member. Accordingly the electrical connections to the first member and the second member must then be established in separate wiring principle alternative to the PCB.

In FIG. 2 is illustrated a situation where a force F has been applied to the first member (1) which implies change in the capacitance of the capacitor that's constituted by the first and the second member (1,4). The CDC will be able to detect the difference in capacitance and thereby the generated input. The force F will typically be a users finger. Due to the mechanical construction, the force F need not be generated by a conductive member, as would otherwise be required had only capacitor technology been utilised.

In a further embodiment, illustrated with reference to FIGS. 3 and 4 a recess (6) is extruded respectively worked in the metal plate, being the first member (1) and the front panel of the apparatus. Thus the gap, i.e. the distance d between the two members (1,4) making up the conductor can be controlled very accurately and the spacer is not needed. The metal plate (1) may be attached to the carrier with adhesive or glue.

In comparison to the embodiment described with reference to FIGS. 1 and 2 wherein a spacer (5) was used, the recess in these embodiments provides a stiff surrounding construction around the pre-processed areas, corresponding to the recesses. Obviously the material from which the spacer is manufactured may also be selected from very stiff non-conductive materials, but due to machining inaccuracies, mounting tolerances etc, a more precise distance d is achieved with this embodiment.

The difference in the embodiments according to FIGS. 3 and 4 being the shape of the recess, i.e. the manner of pre-processing the front panel (1). In the embodiment according to FIG. 3, an indication is given on the front panel (1) as to where the input device is placed on the front panels surface, whereas in FIG. 4 this information may be invisible.

If a thicker metal plate is desired, as illustrated with reference to FIGS. 5 and 6 a larger recess (6) is milled in the metal plate (1), creating space for the carrier (2) of the conductive pad (4). The sensor cell may afterwards be formed by milling a small recess for each button or sensor cell.

The cells for the individual capacitors may also be made by using a spacer (5) with holes for each capacitor.

The example in FIG. 7 illustrates an embodiment which supports input of ten different key numbers (buttons) (0, 1, . . . 9). The matrix registers input and transfers the input via four input terminals (A, B, C, D) which terminals are connected to a CDC (not illustrated) and eventually to a micro-processor.

The sense principle is:

Detected input on input A->key #1 activated
Detected input on input B->key #3 activated
Detected input on input C->key #7 activated
Detected input on input D->key #9 activated
Detected input on input A and B->key #2 activated
Detected input on input A and C->key #4 activated
Detected input on input B and C->key #5 activated
Detected input on input B and D->key #6 activated
Detected input on input C and D->key #8 activated
Detected input on input A and D->key #0 activated

The sensing principle shall be understood such that the conductors indicated by the numbers 0 through 9, being the buttons for example in an alpha-numeric key pad are configured to respond to a physical deformation as explained above. The buttons are electrically interconnected as indicated by the lines 20.

The buttons 2, 4, 5, 6, 8, 0 comprises two separate capacitors. These are in practice created by for example providing two adjacent second members on a PCB (printed circuit board) and in the pre-processed section on the rear side of the front panel create two distinct first members. Where the front panel is non-conductive the first members may be created by applying a conductive layer, superposed the second sections, and where the front panel is conductive, an insulating layer is placed superposed the gap between the second members on the PCB.

As for example button # 5 is depressed input will be detected at terminals B and C due to the electrical connections via buttons # 3 and # 7. Depressing button #7 will only generate an input in terminal C and so forth.

The example illustrated in FIG. 8 receives input of eight different touch cells (41 . . . 48) each having a dedicated input line (41′ . . . 48′). The pad is sensitive for circular movements performed on the touch pad by the finger of the user. In the illustrated example 8 capacitors are arranged in the circular configuration but naturally more or less capacitors may be arranged.

It is clear that as the distance d (see FIGS. 1 and 2) is physically changed thereby generating the input, a finger travelling around the circular configuration as illustrated in FIG. 8, will at some point activate two adjacent capacitors, for example 41 and 42.

A similar situation will arise when the sensors are arranged in an array as illustrated in FIG. 9, where four capacitors/sensors (51,52,53,54) are arranged. Each sensor again has its own separate input line (51′, 52′, 53′, 54′). The pre-processed section in the front panel is indicated by the line 55.

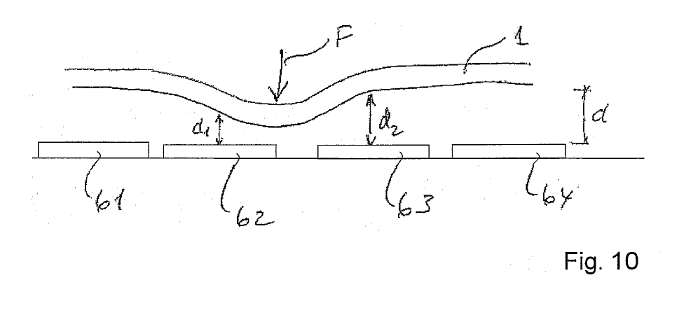

Turning to FIG. 10 an exaggerated illustration clarifying the situation where a force F, for example a users finger travels along a pre-processed section of the front panel 1 superposed a plurality of sensors (61, 62, 63, 64) is illustrated.

The force F will create a deformation in the front panel, thereby changing the distance d, which is the original distance the system is designed with. The change in distance is as explained above the input used for carrying out the predetermined routines programmed in the microprocessor. The CDC will be able to detect minute changes in the distance, such that the distance d1 is communicated to the CDC in the form of the capacitance of the sensor 62 by capacitors 62 separate input line. Likewise the distance d₂ indicating the capacitance of sensor 63 will be communicated by separate input line to the CDC.

The CDC is able to differentiate between the two different inputs, created by the difference in distance d1 and d2. The input to the micro-processor will therefore be in the shape of signals making it possible for the microprocessor to determine the position of the force F, and thereby create for example continuous scrolling along an array. The deflection of the front panel has been exaggerated for illustrative purposes. It is also to be understood that the figure serves to illustrate the principle, and actual embodiments may be constructed with more or fewer capacitors etc.

1. Apparatus including a front panel, where input to the apparatus is performed via the front panel, where at least the side of the front panel opposite to the apparatus front side is provided with an electrically conductive material or the front panel itself is made from a conductive material and that a detection device for sensing user given control commands in terms of activation on said front panel is provided, where said front panel has an extend in a first plane defined by an X and Y axis, where the activation is performed with a the finger by a force along a Z-axis substantially perpendicular to the X-Y plane of said front panel said device comprising:
a first member being the front panel which is pre-processed to have a certain ability to be depressed along the Z-axis upon activation from a finger; and;
said first member being configured to act as one electrode of a capacitor; and;
a second member being made from a conductive material and configured to act as the other electrode of a capacitor;
where the first member electrode being electrical isolated from the second member electrode; and
where the pre-processing of the first member is superposed the second member, and the first member and the second member are assembled such that the assembly constitutes an electrical capacitor having as electrodes, the electrodes of the first and the second members.

2. Apparatus according to claim 1 wherein a plurality of pre-processed sections are arranged in an array or circular configuration, superposed a corresponding array or circular configuration of second members, whereby a force along the horizontal plane of the front panel will generate a dynamic input, such that the relative movement of the force along the array or circle generates the input.

3. A detection device according to claim 1, where the force activated in the Z-axis direction is detected as a magnitude of force with proportional changes in the capacity of the capacitor that is constituted by the first member electrode and the second member electrode.

4. A detection device according to claim 1, where the proportional changes detected may be used to provide a control function that act with a speed according to the applied force.

5. A detection device according to claim 1, where the second member may be mounted directly on a PC board.

6. A detection device according to claim 1, where the second member may be mounted on a nonconductive carrier.

7. A detection device according to claim 1 where the physical distance between the first and the second member is obtained fully or partly as part of the support material of the assembly.

8. A detection device according to claim 1 where a touch sensor detects the changes in capacity by means of a capacity to digital converter measurement principle.

9. A detection device according to claim 1 where the first member is a recess extruded in or with the cover plate.

10. A detection device according to claim 1 where the first member has one or more recess milled or etched on the backside of the cover plate.

11. An interactive media player having integrated a front panel with a detection device according to claim 1, where the cover plate of the detection device is located fully visible on the media player when this is in the mode of normal operation.

12. An interactive game controller having integrated a front panel with a detection device according to claim 1, where the cover plate of the detection device is located fully visible on the game controller when this is in the mode of normal operation.
